(19) United States
(12) Patent Application Publication
(10) Pub. No.: US 2014/0159553 A1
(43) Pub. Date: Jun. 12, 2014

(54) WATERPROOF ELECTRONIC DEVICE

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventor: JIAN-GUO WU, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/864,272

(22) Filed: Apr. 17, 2013

(30) Foreign Application Priority Data
Dec. 7, 2012 (CN) 201210521964.1

(51) Int. Cl. H05K 5/00

(52) U.S. Cl. CPC H05K 5/0004
USPC 312/223.1

(57) ABSTRACT

A waterproof electronic device with waterproof function is provided. The device includes a top cover, a bottom cover, and a waterproof loop. The top cover defines an upper sidewall and a distal end of the upper sidewall being bent outwardly. The bottom cover defines a groove. The waterproof loop is located in the groove. When the waterproof loop is pressed by the bent distal end to engage in the groove, the waterproof loop is deformedly sandwiched by the bent distal end and the bottom cover. Therefore, the bent distal end of the top cover, the waterproof loop, and a sidewall of the bottom cover are adhered each other, and establishing a seamless connection between the top cover and the bottom cover.

### BACKGROUND

1. Technical Field

The disclosure relates to an electronic device and, more particularly, to a waterproof electronic device.

2. Description of Related Art

Screws are often used between a top cover and a bottom cover of an electronic device, therefore, water can easily flows into the electronic device.

Therefore, what is needed is an electronic device to overcome the described shortcoming.

### BRIEF DESCRIPTION OF THE DRAWINGS

FIG. 1 is a perspective view of an electronic device in accordance with an exemplary embodiment.

FIG. 2 is an exploded perspective view of the electronic device of FIG. 1.

FIG. 3 is a partially enlarged view of a top cover of the electronic device of FIG. 2.

FIG. 4 is a partially enlarged view of a bottom cover of the electronic device of FIG. 2.

FIG. 5 is a sectional view of the electronic device of FIG. 1.

### DETAILED DESCRIPTION

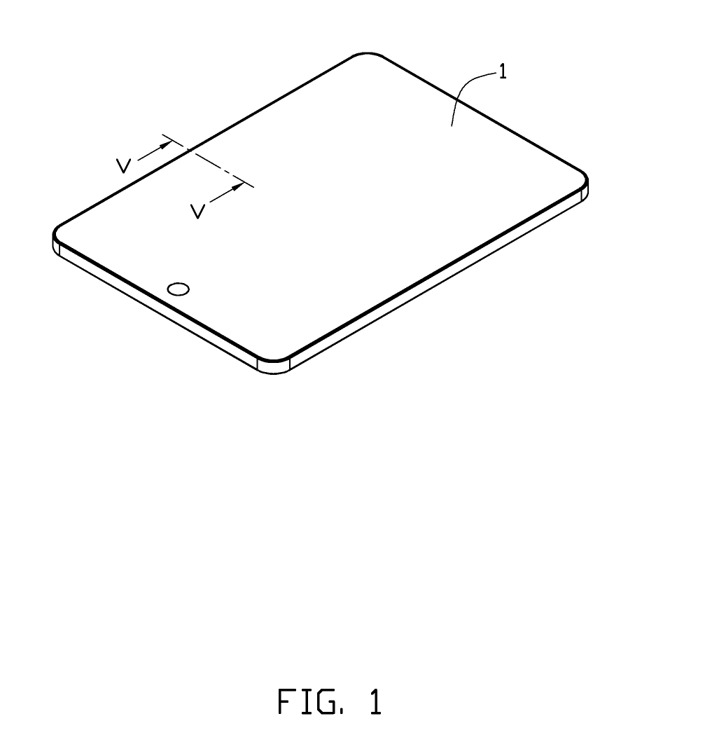

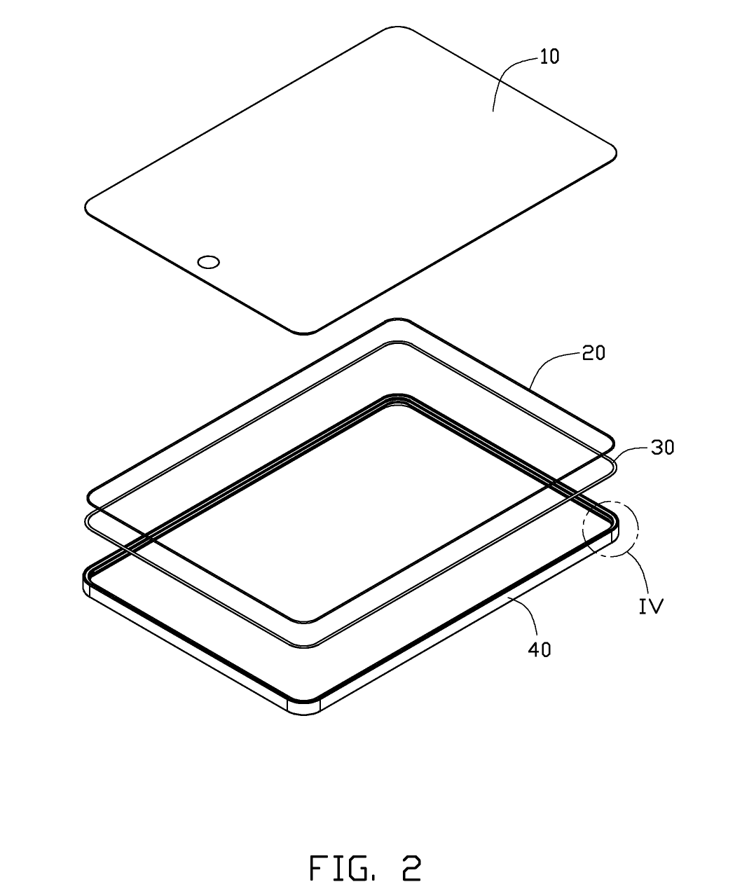

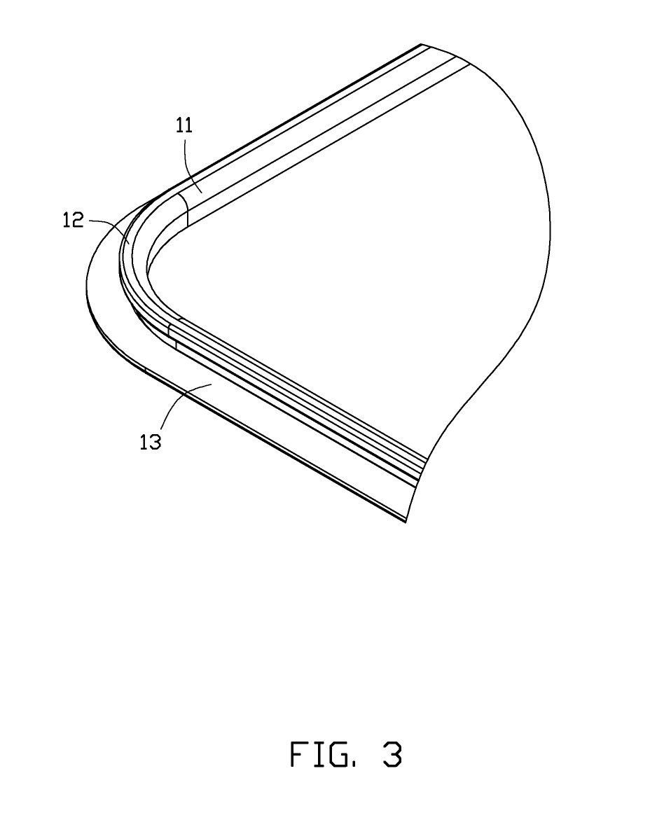

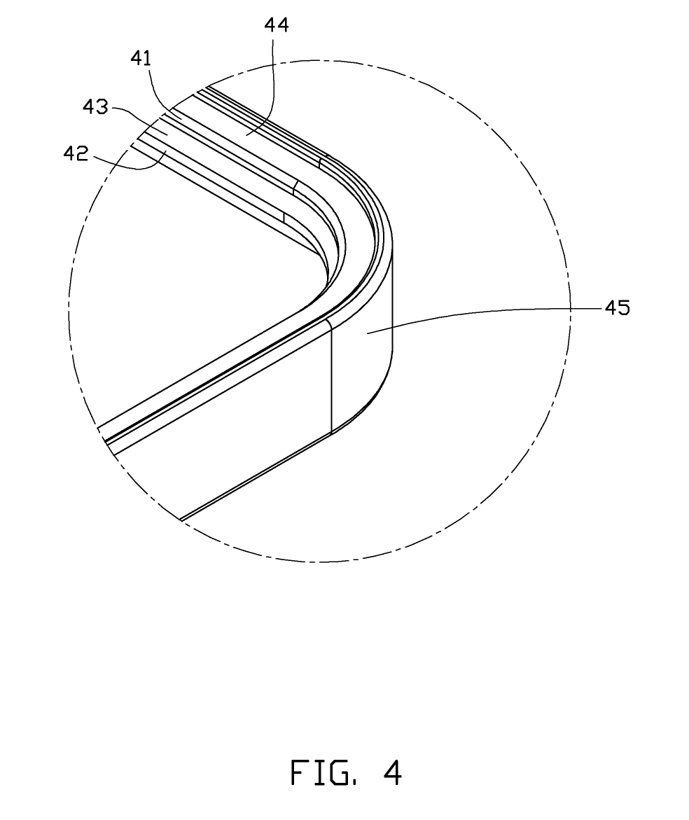

FIGS. 1-4 show an electronic device 1 of one embodiment. The electronic device 1 may be a mobile phone or a tablet computer. The electronic device 1 includes a top cover 10, an adhesive element 20, a waterproof loop 30, and a bottom cover 40. A body of the top cover 10 is a top panel 13. The top panel 13 is made of transparent glass; therefore, a user can look at contents displayed on a screen (not shown) of the electronic device 1 under the top panel 13. A loop-shaped upper sidewall 11 extends along a periphery of the top panel 13 and is perpendicular to the top panel 13. In the embodiment, the upper sidewall 11 is a rectangular shape. A distal end 12 of the upper sidewall 11 is bent outwardly.

The bottom cover 40 includes a bottom panel 46 and a lower sidewall 45 perpendicularly extending from the bottom panel 46. Two spaced protruding boards 41, 42 perpendicularly extend from the lower sidewall 45 and are parallel each other. One of the two protruding boards 41, 42 comes away from the bottom panel 46 and is labeled as an outer protruding board 41. A groove 43 is formed between the two protruding boards 41, 42.

The waterproof loop 30 is made of soft materials, such as silica gel. The waterproof loop 30 deforms when an external force is applied thereto. The waterproof loop 30 is extruded and located in the groove 43. The adhesive element 20 adheres the top cover 10 adhere to an outer surface 44 of the outer protruding board 41. For example, the adhesive element 20 is a loop-shaped double-sided adhesive tape.

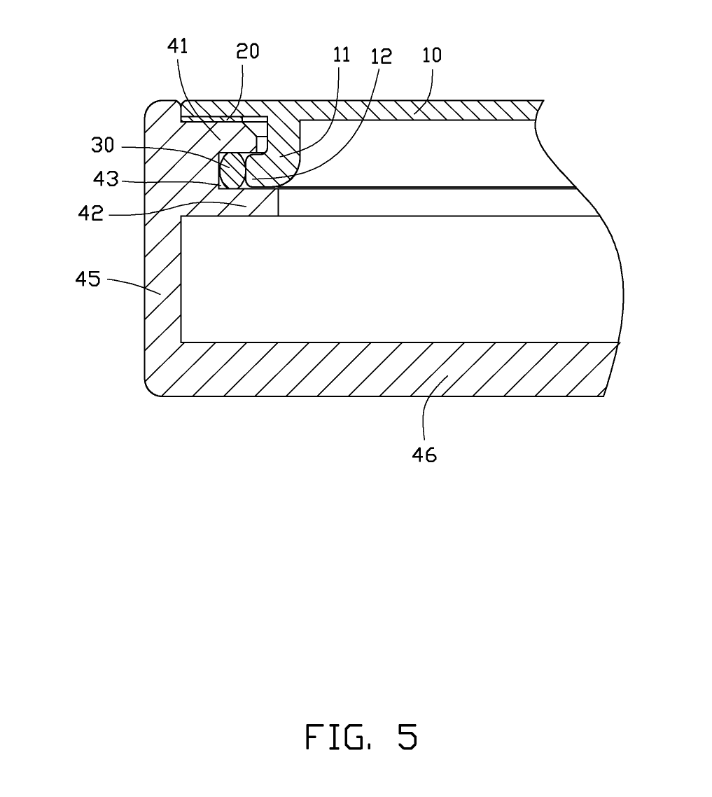

FIG. 5 shows that the top cover 10 is attached to the bottom cover 40, the top panel 13 of the top cover 10 is adhered to the outer surface 44 of the outer protruding board 41 via the adhesive element 20. In addition, the waterproof loop 30 is pressed by the bent distal end 12 to engage in the groove 43, and the waterproof loop 30 is deformedly sandwiched by and between the two protruding boards 41, 42. Furthermore, the waterproof loop 30 is deformedly sandwiched by and between the bent distal end 12 and the lower sidewall 45. The groove 43 fills with the waterproof loop 30. Therefore, the bent distal end 12 of the top cover 10, the waterproof loop 30, and the lower sidewall 45 of the bottom cover 40 are adhered to each other establishing a seamless connection between the top cover 10 and the bottom cover 40. The electronic device 1 is substantially waterproof.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A waterproof electronic device comprising:
a top cover comprising a top panel and a loop-shaped upper sidewall extending along a periphery of the top panel and being perpendicular to the top panel, a distal end of the upper sidewall being bent outwardly;
a waterproof loop;
a bottom cover comprising a bottom panel and a lower sidewall perpendicularly extending from the bottom panel, two spaced protruding boards perpendicularly extending from the lower sidewall, and a groove formed between the protruding boards; and
wherein the top cover is attached to the bottom cover, the top panel is adhered to one of the two protruding boards, the waterproof loop is pressed by the bent distal end to engage in the groove, the waterproof loop is deformedly sandwiched by and between the protruding boards.

2. The waterproof electronic device as recited in claim 1, wherein the waterproof loop is deformedly sandwiched by and between the bent distal end and the lower sidewall.

3. The electronic device as recited in claim 1, further comprising an adhesive element for adhering the top cover to the corresponding protruding board.

4. The waterproof electronic device as recited in claim 3, wherein the adhesive element is a loop-shaped double-sided adhesive tape.

5. The waterproof electronic device as recited in claim 1, wherein the waterproof loop is made of silica gel.
